(19) United States
(12) Patent Application Publication
(10) Pub. No.: US 2009/0289304 A1
(43) Pub. Date: Nov. 26, 2009

(54) CO-INTEGRATION OF MULTI-GATE FET WITH OTHER FET DEVICES IN CMOS TECHNOLOGY

(75) Inventors: Arnaud Pouydebasque, Crolles (FR); Robin Cerutti, Montreal (CA)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignees: KONINKLIJKE PHILIPS ELECTRONICS NV, Eindhoven (NL); ST MICROELECTRONICS (CROLLES 2) SAS, CROLLES (FR)

(21) Appl. No.: 12/296,402

(22) PCT Filed: Mar. 30, 2007
(86) PCT No.: PCT/EP07/53106

§ 371 Date: Oct. 7, 2008

(30) Foreign Application Priority Data
Apr. 7, 2006 (EP) 06300346.1
Mar. 30, 2007 (EP) PCT/EP2007/053106

(51) Int. Cl. H01L 27/12; H01L 21/84; H01L 29/786

(52) U.S. Cl. 257/351; 438/154; 257/E27.112; 257/E29.273; 257/E21.7

(57) ABSTRACT

The present invention relates to a CMOS circuit device on a SOI substrate with an oriented silicon surface, comprising on a first substrate region a FET that has a FET channel region of a first conductivity type, and comprising on a second substrate region a FinFET that has a FinFET channel region of a second conductivity type which is opposite to the first conductivity type. The invention also relates to a method for fabricating such a CMOS circuit device. The fabrication of the multi-gate planar FET comprises, at an intermediate step, forming a FET channel stack with an alternating sequence of layers of a FET material and of a sacrificial material and containing main FET-channel faces, which have the same orientation as the oriented silicon surface. According to the invention, a co-integration of multi-gate FET devices is achieved that ensures high carrier mobilities for both NMOS and PMOS FETs.

The present invention relates to a CMOS circuit device on a SOI substrate. The invention also relates to a method for fabricating such a CMOS circuit device.

MOS (Metal-Oxide-Semiconductor)-based integrated circuits have undergone a continuous development towards higher performance and lower cost. Moore's Law describes and predicts exponential rates of increase in circuit speed and integration density while MOS field-effect transistors (FET) are scaled. As the channel length of a MOSFET shrink below 50 nm, complex channel designs are necessary for achieving desired threshold voltages. Furthermore, short-channel effects must be addressed.

Double-gate or, more generally speaking, multi-gate structures are expected to deliver the lowest channel length for a given gate insulator thickness. FinFETs are widely considered as the most promising candidate for a multi-gate FET structure in this range. A FinFET comprises an active region in the shape of a fin.

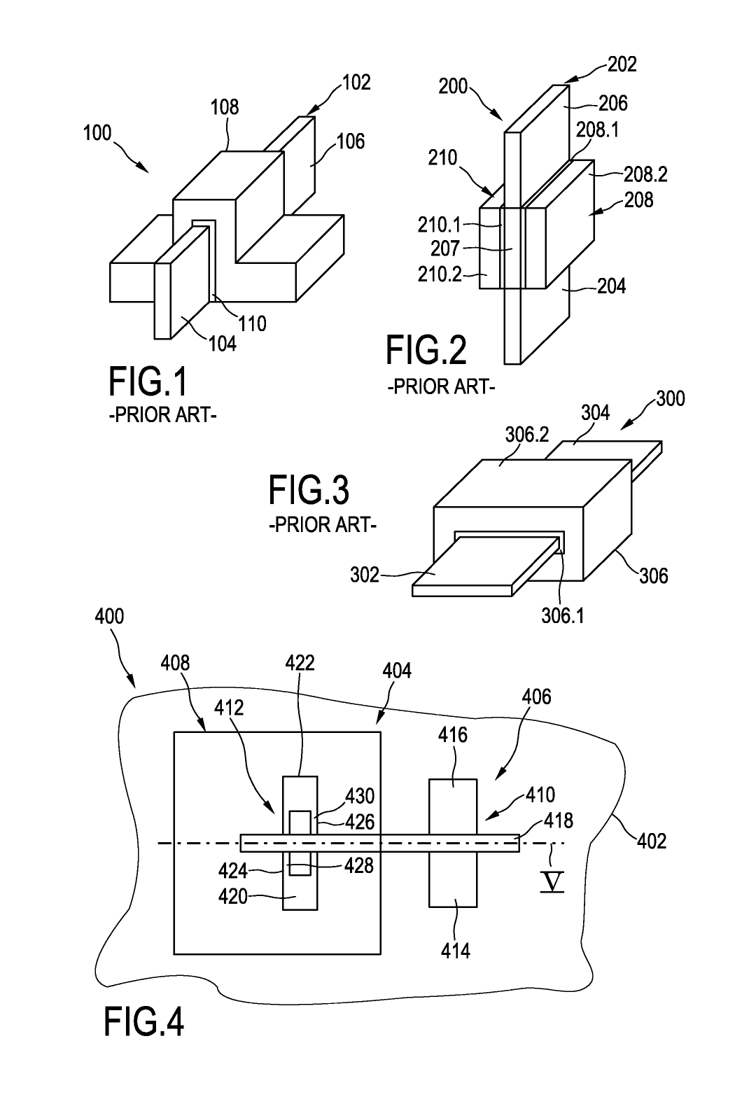

FIGS. 1 to 3 show three examples of known transistor structures, which have been discussed and tested in the art to date.

FIG. 1 shows a perspective view of a typical FinFET 100. On a substrate (not shown) a fin-shaped conduction film 102 forms a source region 104 and a drain region 106 on two sides of a gate structure 108, which encloses a channel region (not visible in this view) on three sides with a shape that resembles the Greek letter Omega. A longitudinal channel direction between source and drain is parallel to the substrate surface. The gate structure 108 and the channel region are separated by a gate insulator layer 110.

In a double-gate FET 200 shown in of FIG. 2, the longitudinal channel direction in a fin-shaped conduction film, also referred to in short as a fin, 202 between a source region 204 and a drain region 206 is perpendicular to a substrate surface (not shown). Thus, the source and drain regions are arranged at different distances from the substrate surface. A channel region 207 between the source and drain regions is enclosed on two sides by gate stacks 208 and 210. The gate stacks each comprise a gate insulation layer 208.1 and 210.1, and a gate electrode layer 208.2 and 210.2, respectively, on both sides of the fin.

In contrast, a planar FET 300 of FIG. 3, which is also referred to as a planar gate-all-around (GAA)-FET has a planar source region 302 and a planar drain region 304, which both extend in a plane that is parallel to an underlying substrate surface (not shown). A gate stack 306 surrounds a channel region (not shown), and comprises ring-shaped gate insulator 306.1 and a gate electrode layers 306.2. This structure has the advantage to be able to stack several conduction channels vertically, i. e., to provide more current per design area, proportionally to the number of channels.

One of the main reasons that enabled the scaling of CMOS devices in recent years is the introduction of novel techniques for improving carrier mobility. One of the most promising techniques is to optimize the channel orientation for improving the intrinsic charge-carrier mobility. Different charge-carrier types are known to have different mobility along different directions in the Silicon crystal. It is well known that electron mobility is highest for the traditional Si substrate/transistor configuration, i.e., a (100) surface with a <110> channel direction, while hole mobility is highest for a (110) surface with a <110> channel direction. A FinFET architecture on a (110) substrate and with a <110> channel direction thus has the advantage of providing an enhanced PMOS performance due to an improved hole mobility.

However, it was found that the most efficient channel orientation for improving the hole mobility at the same time degrades the electron mobility in NMOS devices with the same channel orientation, and vice versa. That is, improving electron mobility in NMOS devices by choosing an optimal channel orientation for electrons degrades the hole mobility in PMOS devices with the same channel orientation. Thus, there is a demand for improving the majority carrier mobilities in both NMOS and PMOS devices of a CMOS circuit device at the same time.

US 2004/0266076 A1 describes a CMOS process for co-integration of a PMOS device in the form of a pFinFET and an NMOS device in the form of a single-gate planar nMOSFET. The disadvantage of that process is that a scaled single-gate MOSFET only achieves relatively poor performance parameters for the NMOS device in comparison with multi-gate FET structures.

Generally, CMOS co-integration of a multi-gate FET with another FET structure is an issue that has not been addressed.

It is therefore preferred to provide a method for fabricating a CMOS circuit device that allows co-integration of a multi-gate FET with another FET structure.

It would also be advantageous to provide a method for fabricating a CMOS circuit that provides high majority-carrier mobility in NMOS as well as PMOS multi-gate FET devices.

Since the invention is best understood on the basis of its method aspects, these aspects will be explained first, before turning to the device aspect of the invention.

Thus, according a first aspect of the invention, a method is provided for fabricating a CMOS circuit device containing on a first substrate region a multi-gate FET that has multiple FET channel region of a first conductivity type, and comprising on a second substrate region a FinFET that has a FinFET channel region of a second conductivity type which is opposite to the first conductivity type. The method comprises the steps of:
providing a silicon-on-insulator, SOI, substrate having an oriented silicon surface;
depositing and structuring a first mask for defining at least one first substrate region for fabrication of the FET and at least one second substrate region for fabrication of the FinFET;
fabricating a FET channel stack in the first substrate region, the FET channel stack having an alternating sequence of layers of a FET material and of a sacrificial material and containing main FET-channel faces, which have the same orientation as the oriented silicon surface;
laterally structuring the FET channel stack using a second mask;
filling the first substrate region with FET material up to the upper edge of the FET channel stack;
depositing and structuring a third mask for defining at least one active FET transistor layer and at least one active FinFET transistor layer in the first and second substrate regions, respectively;
selectively removing the second mask from sections of the first region, which are not covered by the third mask;
selectively removing the first mask from sections of the second region, which are not covered by the third mask;
uncovering a buried oxide layer of the SOI substrate in sections of the first and second substrate regions, which are not covered by the third mask, thereby fabricating in the second region a FinFET channel region with parallel main FinFET-channel faces, which have an orientation perpendicular to that of the oriented silicon surface;
selectively removing the sacrificial layers from the FET channel stack in the first region, thereby forming slit sections extending at different distances from an oxide-layer surface of the SOI substrate and abutting the FET channel region on the two main FET-channel faces; and
fabricating and laterally structuring a multi-gate-FET gate stack and a Fin-FET gate stack on the active transistor layers in the first and second substrate regions, thereby filling the slit sections in the FET channel stack.

The method of the invention provides a co-integration CMOS process flow that enables to fabricate multi-gate FETs with optimized carrier mobility for both types of charge carriers, electrons and holes. Multi-gate FETs, i.e., for instance, two-gate, three-gate, or gate-all-around FET structures, are fabricated according to the invention for both types of charge carriers. That is, the method of the invention allows to have high-mobility multi-gate FETs on PMOS as well as on NMOS regions of a SOI substrate.

While FinFETs and multi-gate FET structures have been known as such in the art, and while a combination of a single-gate FET with a FinFET has also been known, it has not been possible to co-integrate planar multi-gate FETs and FinFETs in the same layout on a CMOS circuit device.

The method of the invention therefore allows to combine the advantages of multi-gate FET devices with the advantages of high-carrier mobility for both electrons and holes, in the respective FET device.

The process of the invention uses a SOI substrate with an oriented silicon surface. The orientation of the silicon surface is given by the crystal plane that forms the silicon surface. A silicon layer in a SOI-substrate with a (100)-oriented silicon surface provides the basis for a process, in which according to the invention a planar multi-gate NMOS FET is co-integrated with a PMOS FinFET. On the other hand, the process of the invention can also be used with a SOI substrate that has a (110)-oriented silicon surface. In this alternative of the invention a planar multi-gate PMOS FET is co-integrated with an NMOS FinFET. Both alternatives provide high majority carrier mobilities in the respective FET channel regions for both NMOS and PMOS FET devices. The FET that has a channel region with an orientation that equals that of the oriented silicon surface of the SOI substrate is also referred to as a planar FET herein. Since FinFETs per se are multi-gate FET devices, reference to a FinFET implies that this is a multi-gate FET structure.

The method of the invention enables the co-integration of a planar multi-gate FET with a FinFET by a particular mask sequence and mask structure. The fabrication of the multi-gate planar FET comprises, at an intermediate step, forming a FET channel stack with an alternating sequence of layers of a FET material and of a sacrificial material and containing main FET-channel faces, which have the same orientation as the oriented silicon surface. The term FET channel stack is used herein to denote a layer stack that contains the layer(s), which serve to form the channel region of the FET. The FET material is a semiconductor material that forms the source, drain and/or channel regions. Typically, the FET material is silicon. However, SiGe can also be used as the FET material. The term main FET- or FinFET channel faces is used herein for those crystal faces of the channel regions that have the largest area.

The sacrificial material is a material that can be removed with high selectivity, that is, without removing the FET material at the same time. The sacrificial material layers protect the sensitive channel region during subsequent processing steps and serve to prepare the formation of the multi-gate structure. They are removed after the formation of the active FET transistor layer, which is the semiconductor layer that in the finalized device contains source and drain regions. The sacrificial material layers then give way to the formation of the gate stack to form the multi-gate planar FET structure. By selectively removing the sacrificial layers from the FET channel stack, slit sections are formed, which will then be filled by a gate dielectric material that in the finalized device abuts the channel region.

This processing of a multi-gate planar FET structure is performed concurrently with the formation of a FinFET in the second substrate region. Only the formation of the FET channel stack is performed while the second substrate region is covered by a mask, which is referred to as the first mask herein.

With the method of the invention, not only device performance in terms of optimum mobility for both PMOS and NMOS multi-gate structures is achieved. Also, the scalability of the device structure is enhanced, since the processing of the invention allows an enhanced short-channel control in the multi-gate FETs. The method of the invention can be used for the production of all kinds of CMOS devices and their applications, such as logic gates, memory cells for SRAM (static random access memory) or DRAM (dynamic random access memory).

In the following, preferred embodiments of the method of the first aspect of the invention will be described. The embodiments can be combined with each other, unless explicitly stated otherwise.

In one embodiment, the step of fabricating the FET channel stack comprises fabricating an alternating sequence of Si layers as the FET material and SiGe layers as the sacrificial material, which sequence comprises at least two SiGe layers. SiGe can be etched with high selectivity over Si, that is, without removing Si as well. A higher Ge content may help to increase the selectivity. A typical Ge content that has been used with success is 20 to 30%.

In a preferred embodiment, the third mask contains a FET mask section that, in a top view, has a shape of a full rectangle, and a FinFET mask section that, in a top view, has a shape of a rectangle with an opening in its centre region. This way, the FinFET is provided with two fin-shaped FinFET channel regions.

Another embodiment additionally comprises the fabrication of a FET of the partially-depleted type, pdFET, on a third substrate region, which pdFET is fabricated in parallel with the FinFET. In this embodiment,
the step of depositing and structuring the first mask includes defining at least one third substrate region for fabrication of the pdFET;
the step of depositing the third mask includes depositing the third mask for at least one active pdFET transistor layer in the third substrate region;
the step of selectively removing the first mask and the second mask from sections of the first and second substrate regions, which are not covered by the third mask.

A pdFET is preferably integrated into a large active area and used, for instance, for Input/Output devices. The process flow of the invention thus offers the possibility to co-integrate SOI pdFETs with FinFETs and planar multi-gate (in particular, GAA) FETs.

Further embodiments of the method of the invention result from embodiments of the CMOS circuit device of the invention, which will be described in the following section.

Note that the invention also allows a co-integration of only a SOI pdFET with a multi-gate FET, without including a FinFET. Therefore, a second method aspect of the invention is formed by a method for fabricating a CMOS circuit device containing, on a first substrate region, a multi-gate FET that has a FET channel region of a first conductivity type, and containing, on a second substrate region, a FET of the partially-depleted type, pdFET, that has a pdFET channel region of a second conductivity type which is opposite to the first conductivity type. The method of this aspect comprises the steps of:
providing a silicon-on-insulator, SOI, substrate having an oriented silicon surface;
depositing and structuring a first mask for defining at least one first substrate region for fabrication of the FET and at least one second substrate region for fabrication of the pdFET;
fabricating a FET channel stack in the first substrate region, the FET channel stack having an alternating sequence of layers of a FET material and of a sacrificial material and containing main FET-channel faces, which have the same orientation as the oriented silicon surface;
laterally structuring the FET channel stack using a second mask;
filling the first substrate region with FET material up to the upper edge of the FET channel stack;
depositing and structuring a third mask for defining at least one active FET transistor layer and at least one active pdFET transistor layer in the first and second substrate regions, respectively;
selectively removing the second mask from sections of the first region, which are not covered by the third mask;
selectively removing the first mask from sections of the second region, which are not covered by the third mask;
uncovering the buried oxide of the SOI substrate in sections of the first and second substrate regions, which are not covered by the third mask, thereby fabricating in the second region a pdFET channel region with parallel main pdFET-channel faces, which have an orientation parallel to that of the oriented silicon surface;
selectively removing the sacrificial layers from the FET channel stack in the first region, thereby forming slit sections extending at different distances from the silicon surface and abutting the FET channel region on the two main FET-channel faces; and
fabricating and laterally structuring gate stacks on the active transistor layers in the first and second substrate regions, thereby filling the slit sections in the FET channel stack.

The method of this aspect of the invention allows a co-integration of a multi-gate FET with a pdFET, which is useful for instance for fabricating Input/Output circuits. In comparison to the method of the first aspect of the invention, the pdFET is obtained by increasing the thickness of the fins so that the carrier transport mainly occurs in the top region of the fin. The resulting structure is equivalent to a SOI device with a SOI film thickness equal to the fin height of the FinFET fabricated in the method of the first aspect of the invention.

According to a second aspect of the invention, a CMOS circuit device on a SOI substrate with an oriented silicon surface is provided. The CMOS circuit device comprises
on a first substrate region, a multi-gate FET with an active multi-gate FET transistor layer that contains, between main FET-channel faces, which have the same orientation as the silicon surface, multiple FET channel regions of a first conductivity type, and with a FET gate stack abutting the main FET-channel faces,
and, on a second substrate region, a FinFET with at least one active FinFET transistor layer that contains, between parallel main FinFET-channel faces, which have an orientation perpendicular to that of the silicon surface, at least one FinFET channel region of a second conductivity type opposite to the first conductivity type, and with a FinFET gate stack abutting the main FinFET-channel faces.

The CMOS circuit device of the second aspect of the invention has the advantages that have already been described in context of the method of the first aspect of the invention. Therefore, reference is made to the respective previous paragraphs.

In the following, preferred embodiments of the CMOS circuit device of the invention will be described. They imply method aspects, which at the same time form preferred embodiments of the method of the first aspect of the invention. The embodiments can be combined with each other, unless explicitly stated otherwise.

In a preferred embodiment, the CMOS circuit device is formed on a silicon surface of the SOI substrate, which is (100)-oriented. This is the most-widely used type of SOI substrate and therefore allows forming the CMOS circuit device at low cost. Consequently, to achieve the high-mobility in both PMOS and NMOS multi-gate FET devices, the FET channel region is an n-channel region, the FinFET channel region is a p-channel region, and the main FinFET-channel faces are (110)-oriented.

An alternative to the previous embodiment is formed by a CMOS circuit device, wherein the silicon surface of the SOI substrate is (110)-oriented, the FET channel region is a p-channel region, the FinFET channel region is an n-channel region, and the main FinFET-channel faces are (100)-oriented. In this embodiment, as explained earlier, the FinFET and planar multi-gate FET structures are provided for respective opposite charge carrier types. Thus, the FinFET is used for NMOS. This is due to the fact that in this embodiment the silicon surface of the substrate provides better mobility for holes than for electrons.

In both alternative embodiments a longitudinal direction of the FET-channel region between a FET source region and a FET drain region is a <110>-direction. This direction provides optimum mobility for both electrons (that is, in the embodiment where the silicon surface of the SOI substrate and the main FET-channel faces are (100) faces) and holes (that is, in case the silicon surface and the main FET-channel faces are (110) faces).

Similarly, in both alternative embodiments of the CMOS circuit, a longitudinal direction of the FinFET-channel region between a FinFET source region and a FinFET drain region is a <110>-direction. This direction exhibits also the best mobility for both electrons and holes in a FinFET.

The FET gate stack preferably forms a gate-all-around structure, that is, it is abutting the FET-channel region on all faces. The gate-all-around structure is able to stack several conduction channels vertically. That is, it provides more current per design area, proportionally to the number of channels.

Preferably, the first substrate region is a doped well of a first conductivity type, and the second substrate region is a doped well of a second conductivity type. This refers to typical NMOS and CMOS wells in a SOI substrate. The FET and the FinFET are preferably arranged on the oxide layer of the SOI substrate above the respective doped well.

In a preferred embodiment, the FET transistor layer contains a FET channel stack that has two slit sections extending at different distances from the silicon surface, which slit sections are filled with dielectric material and form sections of a FET-gate dielectric layer of the FET gate stack. To form the preferred GAA structure, the FET-gate stack continues on side faces of the FET channel region, which are oriented perpendicular to the main FET-channel faces.

The active FET transistor layer preferably comprises two parallel fin-shaped FinFET channel regions between a FinFET source and a FinFET drain region, the FinFET channel regions having a distance from each other in a direction perpendicular to the main FinFET-channel faces. Preferably, the FinFET gate stack extends between the two FinFET channel regions, thus forming a FinFET active layer stack having a stacking direction parallel to the silicon surface.

In a preferred embodiment, the CMOS circuit device further contains, on a third substrate region, a FET of the partially-depleted type, pdFET, which pdFET comprises an active pdFET transistor layer with a pdFET channel region adjacent to a pdFET-channel face, which has an orientation parallel to that of the silicon surface, and further comprises a pdFET gate stack abutting the the pdFET channel face. Preferably, the third substrate region is a doped well of the same conductivity type as the second substrate region.

A further device aspect of the invention is formed by a CMOS circuit device on a SOI substrate with an oriented silicon surface, comprising
on a first substrate region, a multi-gate FET with an active multi-gate FET transistor layer that contains, between main FET-channel faces, which have the same orientation as the silicon surface, multiple FET channel regions of a first conductivity type, and with a FET gate stack abutting the main FET-channel faces, and,
on a second substrate region, a FET of the partially-depleted type, pdFET, with an active pdFET transistor layer that contains, adjacent to a pdFET-channel face, which has an orientation parallel to that of the silicon surface, a pdFET channel region of a second conductivity type, and with a pdFET gate stack abutting the the pdFET channel face.

In the following, preferred embodiments of the invention will be described in more detail. For this, reference is made to the enclosed figures.

FIGS. 1 to 3 show three examples of multi-gate transistor structures according to the prior art.

FIG. 4 shows a schematic top view of a co-integration region of a CMOS circuit device according to an embodiment of the invention.

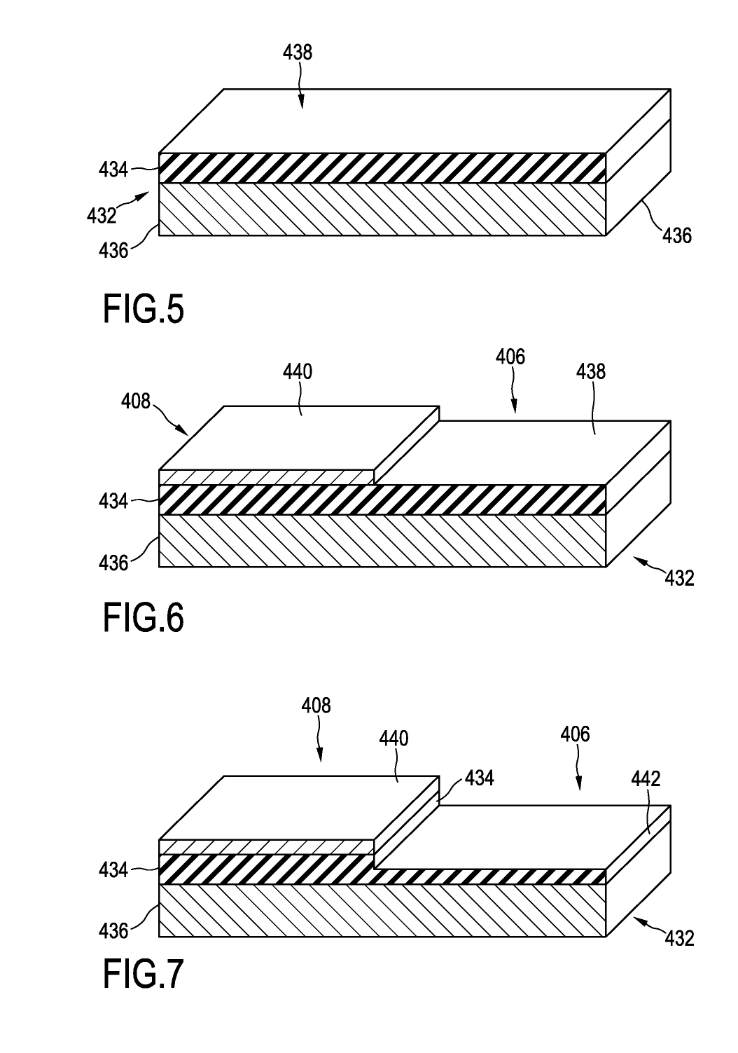

FIGS. 5 to 15 show respective perspective sectional views of the CMOS circuit device of FIG. 4 at different stages of its fabrication.

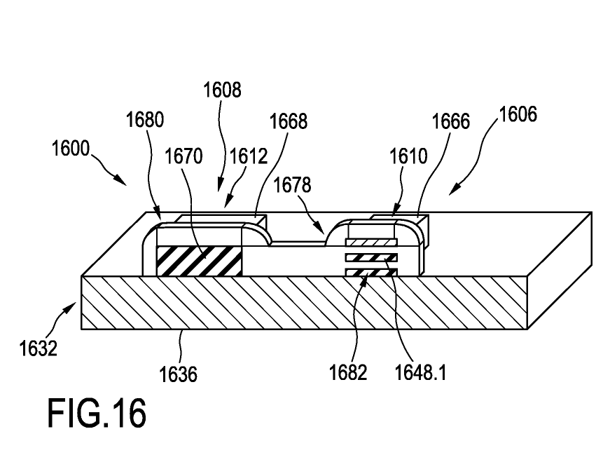

FIG. 16 shows a perspective sectional view of an alternative CMOS circuit device at a processing stage corresponding to that shown in FIG. 15.

FIG. 4 shows a schematic top view of a co-integration region of a CMOS circuit device 400 according to an embodiment of the invention. The view of FIG. 4 is simplified and schematic in order to focus on the main structural features in the context of the present invention. Only a section of the CMOS circuit device 400 is shown, which is indicated by an outline 402. The shown section of the CMOS circuit device 400 contains a co-integration region 404. In the co-integration region 404, a first substrate region 406 contains an NMOS FET 410. A second substrate region 408 contains a PMOS FET 412. The structure of NMOS FET 410 and PMOS FET 412 is only schematically indicated in FIG. 4 and will be described in further detail in the context of the following figures. However, it should already be noted at this point, that in the present embodiment NMOS FET 410 is a multi-gate FET in the form of a planar GAA FET, with a source region 414 and a drain region 416. It is understood that the position of source and drain regions 414 and 416, respectively, can also be interchanged. Between the source and drain regions 414 and 416, a channel region is defined by the extension of a gate structure 418 in the direction from source 414 to drain 416. Note also that the first and second substrate regions form different lateral regions of the substrate. They typically also include doped wells of a respective conductivity type as known in SOI CMOS technology, but which are not shown in the Figures.

The PMOS FET is a multi-gate FinFET structure having a source region 420 and a gate region 422. Again, the arrangement of source and drain regions 420 and 422 can be interchanged. While the planar GAA FET 410 has an active transistor layer, which contains the plain of source 414, drain 416 and the intermediate channel region in a (100)-face of the silicon surface of the SOI substrate, the main faces 424 and 426 of the PMOS FinFET 412 are (110)-silicon faces. Note that the original top silicon layer of the SOI substrate is not present anymore in all lateral regions of the CMOS circuit device, particularly in the regions 408 and 408 shown in the FIGS. 4 to 15. However, as will become apparent from the device processing described below, the orientation of the main faces 424 and 426 is inherited from that of the original top silicon layer of the SOI substrate. The active transistor layer forms fin shaped regions 428 and 430 that comprise a channel region under the gate structure 418, which laterally also extends in the area between the planar GAA FET 410 and the FinFET 412.

More structural details will be come apparent from the further description of an embodiment of a method for fabricating the CMOS circuit device 400 of FIG. 4 with reference to the FIGS. 5 to 15.

FIGS. 5 to 15 show respective sectional views of the CMOS circuit device of FIG. 4 at different stages of its fabrication. The sectional plain, which is consistently used in FIGS. 5 to 15 is indicated by a dashed line V in FIG. 4.

FIG. 5 shows a section of a SOI substrate 432. Only a top silicon layer 434 and an underlying buried oxide layer 436 of SOI substrate 432 are shown. The substrate may contain additional layers underneath the buried oxide layer 436. The silicon layer 434 of the present embodiment has a (001) surface 438.

FIG. 6 shows the substrate 432 after the deposition of a hard mask 440. The hard mask 440 is an oxide mask. In the earlier description this mask was referred to as the first mask. In the processing stage that is shown in FIG. 6, the hard mask 440 has been structured by known means such as lithography. The hard mask 440 is after this structuring only present in the second substrate region 408 (cf. FIG. 4), which is the region of the PMOS FinFET 412.

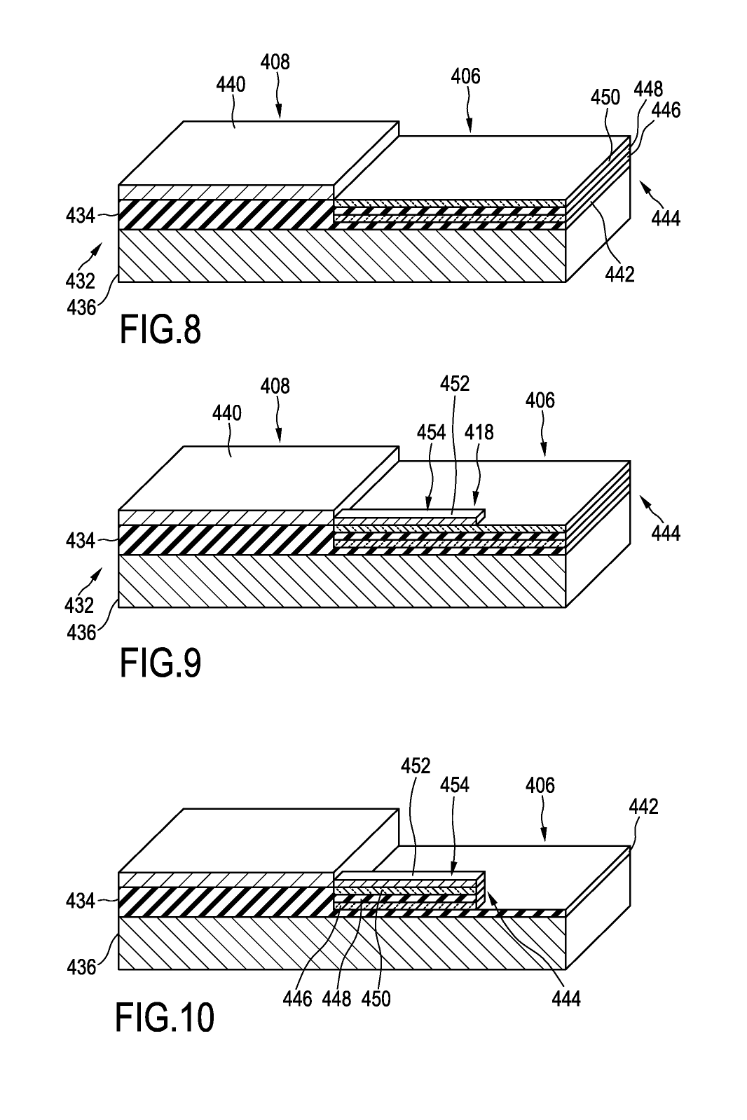

The hard mask 440 serves to protect the silicon layer 434 of the SOI substrate 432 during a subsequent etching step, which serves to thin the silicon layer 434 in the first substrate region 406 down to a thin layer 442 (cf. FIG. 7). In a subsequent selective deposition step, an alternating sequence of silicon and silicon germanium (SiGe) layers is deposited in the first substrate region 406. This way, a layer stack 444 is generated, that in the present example consists of the silicon layer 442, a first SiGe layer 446, a second silicon layer 448 and a second SiGe layer 450 (cf. FIG. 8). Note that the active-layer stack 444 in the first substrate region 406 has the same height as the original silicon layer 434, which remains protected by hard mask 440 in the second substrate region 408.

In a next step a second hard mask 452, which is also referred to in short as the second mask herein, is deposited an structured for defining gate regions in the first substrate regions 406. The second mask is formed by silicon nitride and defined by conventional lithography (cf. FIG. 9).

Subsequently, the active-layer stack 444 is etched in the first substrate region 406 for defining the a first gate region 454 underneath the second mask 452. Note that the removal of the active-layer stack 444 is limited to the layers 446, 448, and 450. The underlying silicon layer 442 is not etched. The oxide layer 436 thus remains covered with silicon in the first substrate region 406 (cf. FIG. 10).

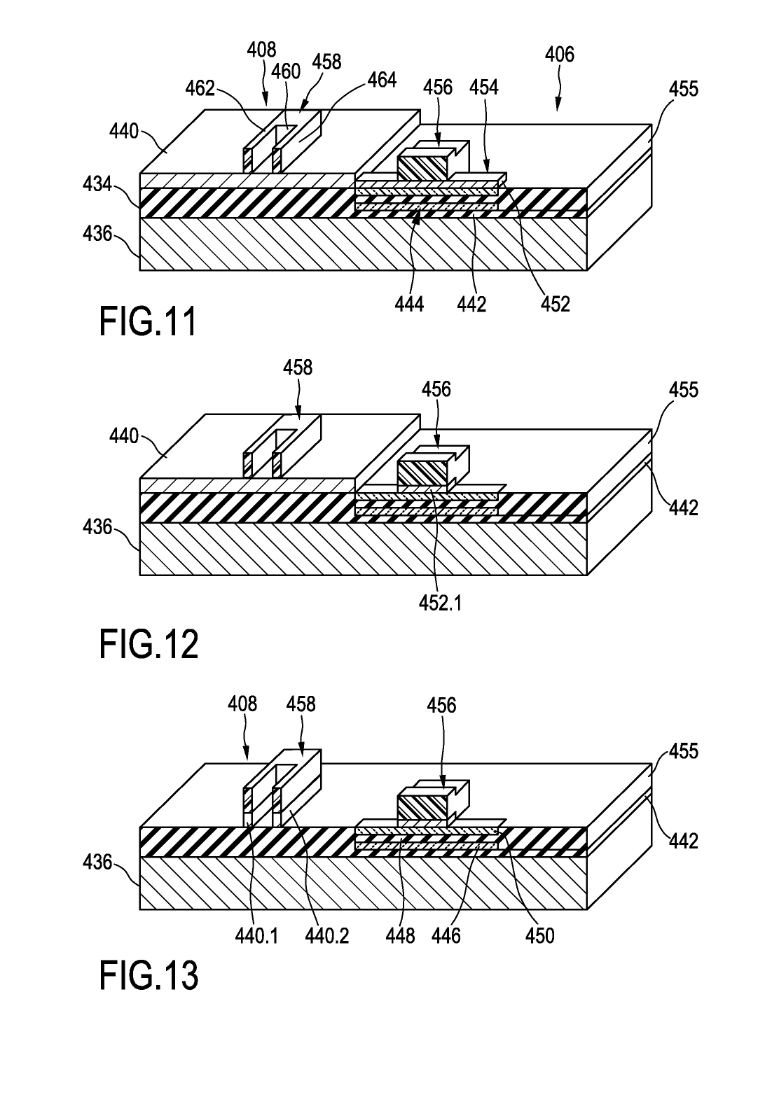

As shown in FIG. 11, the first substrate region 406 is then filled with an epitaxial silicon layer 455 by a selective epitaxy up to the original level, thus reaching the same height as the original silicon layer 434. The epitaxial silicon layer 455 is deposited on top of the silicon layer 442. Furthermore, the lateral shape of a active FET transistor layer in the first substrate region 406 is defined by a third mask 456, which is deposited on top of silicon layer 454 and on top of the first gate region 454, which remains covered by the second hard mask 452. A second section 458 of the third mask is fabricated in the second substrate region 408 for defining a active FinFET transistor layer for the FinFET 412. The mask section 458 has a rectangular shape with an opening 460 between two sidewalls 462 and 464.

In a next processing step, the second mask 452 is anisotropically etched so that only the second-mask section 452.1 remains, which is covered by the third mask section 456 (cf. FIG. 12).

Subsequently, also the first mask 440 is removed from the second substrate region 408 by an anisotropic etching step, which leaves only those sections 440.1 and 440.2 of the first mask 440, which are covered by the third mask 458 (cf. FIG. 13).

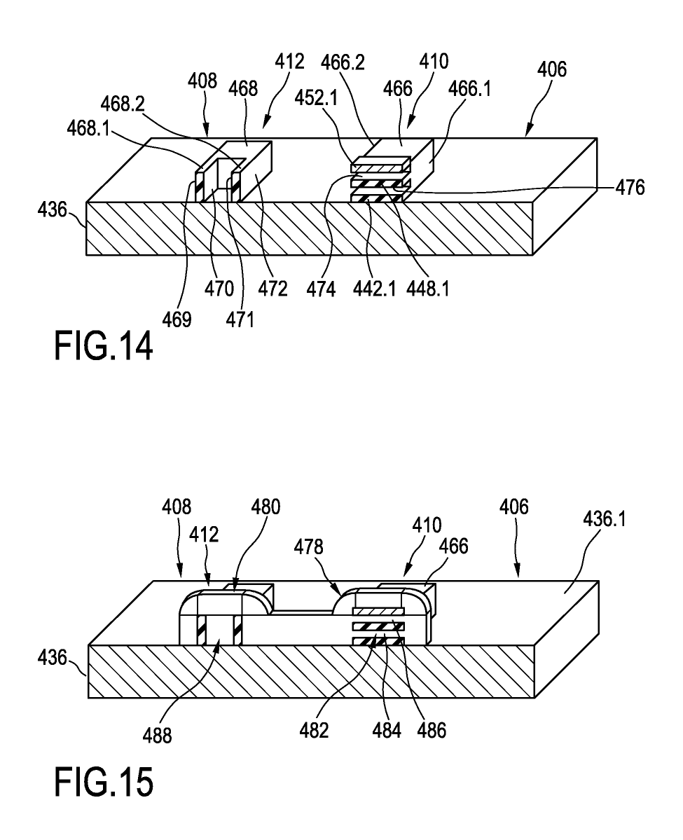

Then, as shown in FIG. 14, a further etching step is performed to remove silicon layers 434, 442, and 455 from the first and second substrate regions 406 and 408, including parts of the active layer stack 444, from those regions, which are not covered by the third mask sections 456 and 458. The third-mask sections 456 and 458 are then removed.

By these steps, the buried oxide layer 436 is uncovered in those sections of the first and second substrate regions 406 and 408, which are not covered by the third mask. The remaining structures form the active transistor layers 466 and 468 of the planar GAA FET 410 and of the FinFET 412, respectively.

Furthermore, a selective etching step of the sacrificial SiGe layers 446 and 450 is performed to obtain the intermediate structure of the active transistor layer 466 shown in FIG. 14. SiGe can be etched with high selectivity over Si, that is, without removing Si as well. A typical Ge content that has been used with success is 20 to 30%. Note that the resulting intermediate structure shown in FIG. 14 is shown schematically in that it omits some remaining sections of the epitaxial silicon layer 455 on lateral side faces 466.1 and 466.2 (not visible in the perspective view of FIG. 14) of the active transistor layer 466. Such remaining sections of the epitaxial silicon layer 455 support the remaining section 452.1 of the second mask 452, and in one embodiment also support remaining second-silicon-layer section 448.1, which forms a multiple-channel region of the active multi-gate FET transistor layer 466 in the planar GAA FET 410.

The multiple-channel region 448.1 of the active layer 466 of the planar GAA FET 410 has upper and lower faces 474 and 476 (the latter not being visible in FIG. 14 due to the chosen perspective), which are (001)-oriented. The upper and lower faces 474 and 476 are to form main FET-channel faces of the planar GAA FET 410. Of course, the exact position of conductive channels is defined by the position of the gate stack.

The processing as described to this point has also allowed to define fin-shaped FinFET channel regions 468.1 and 468.2 in the active transistor layer 468 of the FinFET 412. The FinFET channel regions 468.1 and 468.2 have side faces 469, 470, 471 and 472, which are (110)-oriented. The side faces 469 to 472 are to form main FinFET-channel faces of FinFET 412. The FinFET channel regions have a distance from each other in a direction perpendicular to the main FinFET-channel faces.

The remaining steps for definition of a gate stack 478 of the planar GAA FET 410 and 480 of the FinFET 412 (cf. FIG. 15) are known from standard CMOS processes. The detailed structure of the gate stack 478 is well known in the art and therefore not represented in the Figures of the present application. The planar GAA FET 410 thus contains in its active transistor layer 466 a multi-gate-FET channel layer stack 482 that has two slit sections 484 and 486, which extend at different distances from an oxide-layer surface 436.1 of the oxide layer 436 of SOI substrate 432. The slit sections are filled with dielectric material and form sections of a FET-gate dielectric layer of the multi-gate-FET gate stack 478. On the other hand, the FinFET gate stack 480 extends between the two FinFET channel regions 468.1 and 468.2, thus forming a FinFET active layer stack 488 having a stacking direction parallel to the silicon surface.

According to the process, which has been described, transport of holes in PMOS FinFET 412 will occur in the (110) direction, and transport for electrons in NMOS planar GAA FET 410 will occur in (100) direction. This forms an optimum mobility schema for the multi-gate architectures.

It is noted that the process flow described with respect to the FIGS. 5 to 15 forms a layout example, namely, using a FinFET and a planar GAA for co-integration. However, any kind of layout is possible, according to the designer's choice. In particular, the substrate regions for the PMOS and NMOS FET devices need not be immediately adjacent to each other and the gate stack need not continue between the devices. Inverters, NOR, NAND, SRAM cells, etc. have such a gate connection between NMOS and PMOS. Thus, the reason for showing such a connection in the present embodiment is to represent a basic circuit cell and to show that CMOS operation (NMOS and PMOS) is indeed possible.

FIG. 16 shows a perspective sectional view of an alternative CMOS circuit device at a processing stage corresponding to that shown in FIG. 15. The device is similar to that of FIG. 15, except for the fact that the FinFET is replaced by a SOI partially depleted (pd) FET 1612. The processing of the pdFET 1612 substantially corresponds to that of FinFET 412. However, by using an alternative mask layout, fins 470, 472 of FinFET 412 “merge” into one pdFET channel region 1670 such that during operation of the pdFET 1612 a carrier transport mainly occurs in the top region of the active layer 1670. The height of the active layer is in the range of 50 nm and above, thereby giving rise to a partial depletion during operation. Such a device can of course be used in combination with a FinFET, which is fabricated along the processing scheme explained before. Also, as mentioned before, the gate stack 1678 need not continue between adjacent FET devices.

When interpreting the present description and its associated claims, expressions such as “comprise”, “include”, “incorporate”, “contain”, “is”, and “have” are to be construed in a non-exclusive manner, namely construed to allow for other items or components, which are not explicitly defined also to be present. Reference to the singular is also to be construed in be a reference to the plural and vice versa.

Furthermore, the invention may also be embodied with less components than provided in the embodiments described here, wherein one component carries out multiple functions. Just as well may the invention be embodied using more elements than depicted in the Figures, wherein functions carried out by one component in the embodiment provided are distributed over multiple components.

A person skilled in the art will readily appreciate that various parameters disclosed in the description may be modified and that various embodiments disclosed and/or claimed may be combined without departing from the scope of the invention.

It is stipulated that the reference signs in the claims do not limit the scope of the claims, but are merely inserted to enhance the legibility of the claims.

In the description above, it will be understood that when an element such as layer, region or substrate is referred to as being “on” or “onto” another element, the element is either directly on the other element, or intervening elements may also be present.

1. A CMOS circuit device made on a SOI substrate with an oriented silicon surface, comprising
on a first substrate region, a multi-gate FET with an active multi-gate FET transistor layer that contains, between main FET-channel faces, which have the same orientation as the silicon surface, multiple FET channel regions of a first conductivity type, and a multi-gate-FET gate stack abutting the main FET-channel faces,
and, on a second substrate region, a FinFET with at least one active FinFET transistor layer that contains, between parallel main FinFET-channel faces, which have an orientation perpendicular to that of the silicon surface, at least one FinFET channel region of a second conductivity type opposite to the first conductivity type, and with a FinFET gate stack abutting the main FinFET-channel faces.

2. The CMOS circuit device of claim 1, wherein the silicon surface of the SOI substrate is (100)-oriented, the multiple FET channel regions are n-channel regions, the FinFET channel region is a p-channel region, and the main FinFET-channel faces are (110)-oriented.

3. The CMOS circuit device of claim 1, wherein the silicon surface of the SOI substrate is (110)-oriented, the multiple FET channel regions are p-channel regions, the FinFET channel region is an n-channel region, and the main FinFET-channel faces are (100)-oriented.

4. The CMOS circuit device of claim 1, wherein a longitudinal direction of the multiple FET-channel regions between a multi-gate-FET source region and a multi-gate-FET drain region is a <110>-direction.

5. The CMOS circuit of claim 1, wherein a longitudinal direction of the FinFET-channel region between a FinFET source region and a FinFET drain region is a <110>-direction.

6. The CMOS circuit device of claim 1, wherein the multi-gate-FET gate stack is abutting the multiple FET-channel regions on four faces, thus forming a gate-all-around structure.

7. The CMOS circuit device of claim 1, wherein the first and second substrate regions contain doped wells of opposite conductivity types.

8. The CMOS circuit of claim 1, wherein the active multi-gate FET transistor layer contains a multi-gate-FET channel layer stack that has two slit sections extending at different distances from an oxide-layer surface of the SOI substrate, which slit sections are filled with dielectric material and form sections of a FET-gate dielectric layer of the FETgate stack.

9. The CMOS circuit of claim 8, wherein the multi-gate-FET gate stack continues on side faces of the multi-gate-FET channel region, which are oriented perpendicular to the main FET-channel faces.

10. )The CMOS circuit of claim 1, wherein the active FET transistor layer comprises two parallel fin-shaped FinFET channel regions between a FinFET source and a FinFET drain region, the FinFET channel regions have a distance from each other in a direction perpendicular to the main FinFET-channel faces.

11. The CMOS circuit of claim 10, wherein the FinFET gate stack extends between the two FinFET channel regions, thus forming a FinFET active layer stack having a stacking direction perpendicular to the main FinFET-channel faces.

12. The CMOS circuit of claim 1, further containing, on a third substrate region, a FET of the partially-depleted type, pdFET, which pdFET comprises an active pdFET transistor layer with a pdFET channel region adjacent to a pdFET-channel face, which has an orientation parallel to that of the silicon surface, and further comprises a pdFET gate stack abutting the the pdFET channel face.

13. The CMOS circuit of claim 12, wherein the third substrate region is a doped well of the same conductivity type as the second substrate region.

14. A CMOS circuit device made on a SOI substrate with an oriented silicon surface, comprising
on a first substrate region, a multi-gate FET with an active multi-gate FET transistor layer that contains, between main FET-channel faces, which have the same orientation as the silicon surface, multiple FET channel regions of a first conductivity type, and a multi-gate-FET gate stack abutting the main FET-channel faces, and,
on a second substrate region, a FET of the partially-depleted type, pdFET, with an active pdFET transistor layer that contains, adjacent to a pdFET-channel face, which has an orientation parallel to that of the silicon surface, a pdFET channel region of a second conductivity type, and a pdFET gate stack abutting the the pdFET channel face.

15. A method for fabricating a CMOS circuit device containing on a first substrate region a multi-gate FET that has multiple FET channel regions of a first conductivity type, and comprising on a second substrate region a FinFET that has a FinFET channel region of a second conductivity type, which is opposite to the first conductivity type, comprising the steps of:
providing a silicon-on-insulator, SOI, substrate having an oriented silicon surface;
depositing and structuring a first mask for defining at least one first substrate region for fabrication of the FET and at least one second substrate region for fabrication of the FinFET;
fabricating a FET channel stack in the first substrate region, the FET channel stack having an alternating sequence of layers of a FET material and of a sacrificial material, and containing main FET-channel faces, which have the same orientation as the oriented silicon surface;
laterally structuring the FET channel stack using a second mask;
filling the first substrate region with FET material up to the upper edge of the FET channel stack;
depositing and structuring a third mask for defining at least one active FET transistor layer and at least one active FinFET transistor layer in the first and second substrate regions, respectively;
selectively removing the second mask from sections of the first region, which are not covered by the third mask;
selectively removing the first mask from sections of the second region, which are not covered by the third mask;
uncovering a buried oxide layer of the SOI substrate in sections of the first and second substrate regions, which are not covered by the third mask, thereby fabricating in the second region a FinFET channel region with parallel main FinFET-channel faces, which have an orientation perpendicular to that of the oriented silicon surface;
selectively removing the sacrificial layers from the FET channel stack in the first region, thereby forming slit sections extending at different distances from an oxide-layer surface of the SOI substrate and abutting the FET channel region on the two main FET-channel faces; and
fabricating and laterally structuring a multi-gate-FET gate stack and a FinFET gate stack on the active transistor layers in the first and second substrate regions, thereby filling the slit sections in the FET channel stack.

16. The method of claim 15, wherein the step of fabricating the FET channel stack comprises fabricating an alternating sequence of Si layers as the FET material and SiGe layers as the sacrificial material, which sequence comprises at least two SiGe layers.

17. The method of claim 15, wherein the third mask contains a FET mask section that, in a top view, has a shape of a full rectangle, and a FinFET mask section that, in a top view, has a shape of a rectangle with an opening in its center region.

18. The method of claim 15, further comprising the fabrication of a FET of the partially-depleted type, pdFET, on a third substrate region, which pdFET is fabricated in parallel with the FinFET, wherein
the step of depositing and structuring the first mask includes defining at least one third substrate region for fabrication of the pdFET;
the step of depositing the third mask includes depositing the third mask for at least one active pdFET transistor layer in the third substrate region;
the step of selectively removing the first mask and the second mask from sections of the first and second substrate regions, which are not covered by the third mask.

19. A method for fabricating a CMOS circuit device containing, on a first substrate region, a multi-gate FET that has a FET channel region of a first conductivity type, and containing, on a second substrate region, a FET of the partially-depleted type, pdFET, that has a pdFET channel region of a second conductivity type which is opposite to the first conductivity type, the method comprising the steps of:
providing a silicon-on-insulator, SOI, substrate having an oriented silicon surface;
depositing and structuring a first mask for defining at least one first substrate region for fabrication of the FET and at least one second substrate region for fabrication of the pdFET;
fabricating a FET channel stack in the first substrate region, the FET channel stack having an alternating sequence of layers of a FET material and of a sacrificial material and containing main FET-channel faces, which have the same orientation as the oriented silicon surface;
laterally structuring the FET channel stack using a second mask;
filling the first substrate region with FET material up to the upper edge of the FET channel stack;
depositing and structuring a third mask for defining at least one active FET transistor layer and at least one active pdFET transistor layer in the first and second substrate regions, respectively;
selectively removing the second mask from sections of the first region, which are not covered by the third mask;
selectively removing the first mask from sections of the second region, which are not covered by the third mask;
uncovering the buried oxide of the SOI substrate in sections of the first and second substrate regions, which are not covered by the third mask, thereby fabricating in the second region a pdFET channel region with parallel main pdFET-channel faces, which have an orientation parallel to that of the oriented silicon surface;
selectively removing the sacrificial layers from the FET channel stack in the first region, thereby forming slit sections extending at different distances from the silicon surface and abutting the FET channel region on the two main FET-channel faces; and
fabricating and laterally structuring gate stacks on the active transistor layers in the first and second substrate regions, thereby filling the slit sections in the FET channel stack.
